(19) United States
(12) Patent Application Publication
(10) Pub. No.: US 2026/0006897 A1
(43) Pub. Date: Jan. 1, 2026

(54) METHODS AND APPARATUS TO UTILIZE DEEP TRENCH CAPACITORS WITHIN ISOLATED TRANSISTORS

(71) Applicant: Texas Instruments Incorporated, Dallas, TX (US)

(72) Inventors: Kumar Anurag Shrivastava, Bangalore (IN); Viresh Sharnappa Chinchansure, Bangalore (IN)

(21) Appl. No.: 18/821,697

(22) Filed: Aug. 30, 2024

(30) Foreign Application Priority Data
Jun. 28, 2024 (IN) 202441049725

(51) Int. Cl. H01L 27/06; H01L 21/762; H01L 27/02

(52) U.S. Cl. CPC H10D 84/811; H01L 21/76224; H10D 89/10

(57) ABSTRACT

An example apparatus includes: a first resistor having a first terminal coupled to a supply voltage terminal and a second terminal; a transistor having a gate terminal coupled to a first input terminal, a source terminal coupled to a second input terminal, a body terminal coupled to the source terminal, and a drain terminal coupled to the second terminal of the first resistor; a substrate terminal coupled to ground; an isolation terminal that separates the transistor from the substrate terminal; a second resistor having a first terminal coupled to the isolation terminal and a second terminal coupled to the supply voltage terminal; and a third resistor having a first terminal coupled to the source terminal of the transistor and a second terminal coupled to ground.

### CROSS-REFERENCE TO RELATED APPLICATION

This patent application claims the benefit of and priority to Indian Provisional Patent Application No. 202441049725 filed Jun. 28, 2024, which application is hereby incorporated herein by reference in its entirety.

### TECHNICAL FIELD

This description relates generally to isolated transistors and, more particularly, to methods and apparatus to utilize deep trench capacitors within isolated transistors.

### BACKGROUND

Many applications use isolated transmitter devices to transmit signals in galvanic isolation. As used herein, galvanic isolation refers to the ability for a device to prevent or mitigate the flow of Direct Current (DC) and unwanted Alternating Current (AC) between two parts of a system while still allowing signal and power transfer. For example, a system may implement isolated transmitter devices to electrically couple a first system that uses high voltages unsafe for humans to a second system that uses lower voltages safe for humans. Accordingly, isolated transmitter devices can improve both safety and performance compared to transmitter devices without galvanic isolation.

### SUMMARY

An example apparatus includes: a first resistor having a first terminal coupled to a supply voltage terminal and a second terminal; a transistor having a gate terminal coupled to a first input terminal, a source terminal coupled to a second input terminal, a body terminal coupled to the source terminal, and a drain terminal coupled to the second terminal of the first resistor; a substrate terminal coupled to ground; an isolation terminal that separates the transistor from the substrate terminal; a second resistor having a first terminal coupled to the isolation terminal and a second terminal coupled to the supply voltage terminal; and a third resistor having a first terminal coupled to the source terminal of the transistor and a second terminal coupled to ground.

A second example apparatus includes a first resistor having a first terminal coupled to a supply voltage terminal and a second terminal; a transistor having a gate terminal coupled to a first input terminal, a source terminal coupled to a second input terminal, a body terminal coupled to the source terminal, and a drain terminal coupled to the second terminal of the first resistor; a substrate terminal coupled to ground; an isolation terminal coupled to the second input terminal, wherein the isolation terminal separates the transistor from the substrate terminal; a second resistor (604A) having a first terminal coupled to the isolation terminal and a second terminal coupled to the supply voltage terminal; and a third resistor (410) having a first terminal coupled to the source terminal of the transistor and a second terminal coupled to ground.

A third example apparatus includes a first resistor having a first terminal coupled to a supply voltage terminal and a second terminal; a transistor having a gate terminal coupled to a first input terminal, a source terminal coupled to a second input terminal, a body terminal coupled to the source terminal, and a drain terminal coupled to the second terminal of the first resistor; a substrate terminal coupled to ground; an isolation terminal coupled to the second input terminal, wherein the isolation terminal separates the transistor from the substrate terminal; a second resistor having a first terminal coupled to the isolation terminal and a second terminal coupled to the supply voltage terminal; and a third resistor having a first terminal coupled to the source terminal of the transistor and a second terminal coupled to ground.

### BRIEF DESCRIPTION OF THE DRAWINGS

FIG. 1 is a block diagram of an example environment that includes detector circuitry.

FIG. 2 is a graph illustrating an example implementation of the On-Off-Keying (OOK) format used to transmit data in FIG. 1.

FIG. 3 is a graph illustrating an example implementation of the V_{P}, V_{M}, V_{REF}, and V_{OUT} signals of FIG. 1.

FIG. 4 is an example schematic diagram of the detector circuitry of FIG. 1.

FIG. 5 is a cross-sectional view of an example implementation of the isolated NMOS circuitry of FIG. 4.

FIG. 6A is a schematic diagram of a first previous approach to implement the isolated NMOS circuitry of FIG. 4.

FIG. 6B is a schematic diagram of a second previous approach to implement the isolated NMOS circuitry of FIG. 4.

FIG. 6C is a first schematic diagram of the isolated NMOS circuitry of FIG. 4 when implemented using the examples described herein.

FIG. 7 is an example schematic diagram of the reference circuitry of FIG. 1.

FIG. 8 is a second schematic diagram of the isolated NMOS circuitry of FIG. 4 when implemented using the examples described herein.

FIG. 9 is a third schematic diagram of the isolated NMOS circuitry of FIG. 4 when implemented using the examples described herein.

FIG. 10 is a graph illustrating the performance of the isolated NMOS circuits of FIG. 4.

The drawings are not necessarily to scale. Generally, the same reference numbers in the drawing(s) and this description refer to the same or similar (functionally or structurally) features or parts. Although the drawings show regions with clean lines and boundaries, some or all of these lines and boundaries may be idealized. In reality, the boundaries or lines may be unobservable, blended or irregular.

### DETAILED DESCRIPTION

Galvanic isolation may be implemented within a system in a wide variety of techniques. For example, automotive, medical, and other industries develop various systems that send a signal from a high voltage transmitting device to a galvanically isolated, low voltage receiving device that interacts with humans. Some of these systems include signals that are formatted with using On-Off Keying (OOK), a modulation scheme that varies the power level of the carrier signal between two discrete power levels. In such examples, the receiving device may include isolated N-Channel Metal-Oxide-Semiconductor (NMOS) transistors to detect when the OOK signals switch between power levels. As used above and herein, an isolated NMOS transistor refers to an NMOS transistor that is galvanically isolated from other components within the same integrated circuit (IC). The isolated NMOS transistors help provide the low voltage receiving device with electromagnetic immunity from the high voltage transmitting device.

Implementing an isolated NMOS transistor requires the use of one or more Deep Trench (DT) components within an integrated circuit (IC) to form a physical barrier between the NMOS and adjacent components. The DT components introduce parasitic capacitance that can decrease the gain of devices that utilize the NMOS. In some examples, a device may incorrectly interpret the OOK signal due to decreased gain caused by one or more internal NMOS transistors. Accordingly, DT components can degrade the Signal to noise Ratio (SnR) of a communication device.

Example methods, apparatus, and systems herein implement isolated NMOS transistors that increase the gain of detector circuitry. Example detector circuitry includes a resistor that connects an isolated region within the DT components to a supply voltage, thereby reducing the effective capacitance at the source terminal of the transistor and improving the gain. The example detector circuitry also connects an input terminal that receives the OOK signal to both the source node of the isolated NMOS transistor and the isolated layer of the DT region, thereby charging the parasitic capacitors from two nodes and improving the gain further.

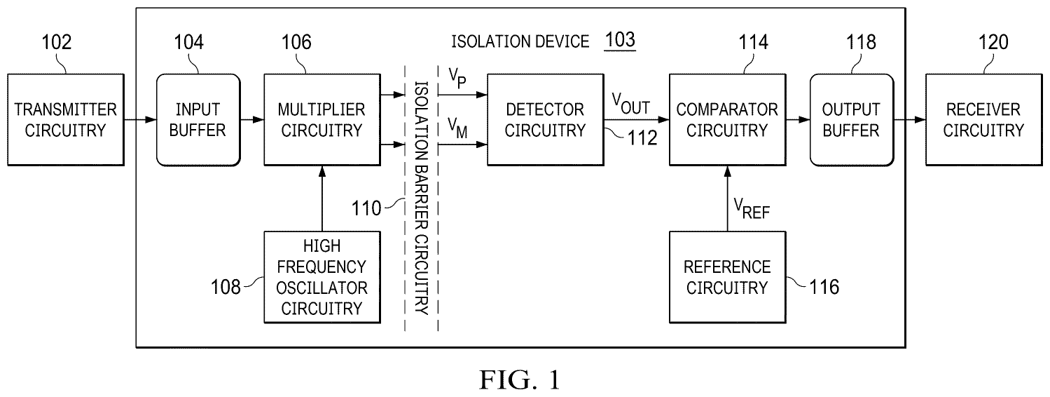

FIG. 1 is a block diagram of an example environment that includes detector circuitry. FIG. 1 includes an example transmitter circuitry 102, an example isolation device 103, and example receiver circuitry 120. The isolation device 103 includes an example input buffer 104, example multiplier circuitry 106, example high frequency oscillator circuitry 108, example isolation barrier circuitry 110, example detector circuitry 112, example comparator circuitry 114, example reference circuitry 116, an example output buffer 118, and example receiver circuitry 120.

The example transmitter circuitry 102 refers to any device that outputs digital data. The digital data may be provided by any type of programmable circuitry, including but not limited to programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). In some examples, the transmitter circuitry 102 operates at a comparatively high voltage and a comparatively high data transfer rate.

Within the isolation device 103, the input buffer 104 stores digital data because, in the example of FIG. 1, the transmitter circuitry 102 outputs data at a faster rate than the multiplier circuitry 106 can perform operations. The multiplier circuitry 106 implements OOK modulation by multiplying data from the input buffer 104 with a high frequency signal from the high frequency oscillator circuitry 108. Thus, the multiplier circuitry 106 outputs a high frequency signal to represent a logical 1 bit and does not output a signal to represent a logical 0 bit (e.g., a signal at approximately 0 Volts represents a logical 0 bit). The multiplier circuitry 106 also converts the digital data stream into an analog, differential signal when performing multiplication operations. The output terminals of the multiplier circuitry 106 are coupled to the isolation barrier circuitry 110.

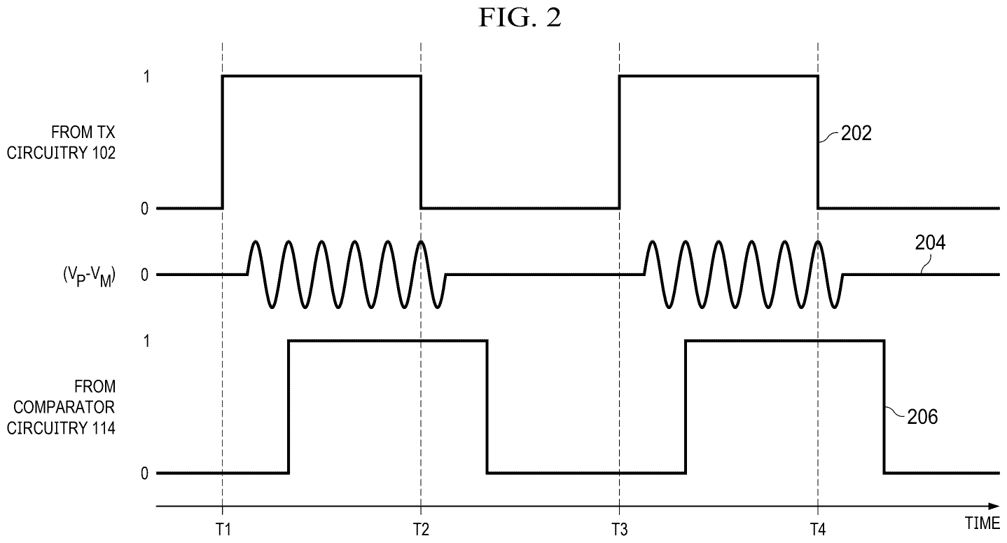

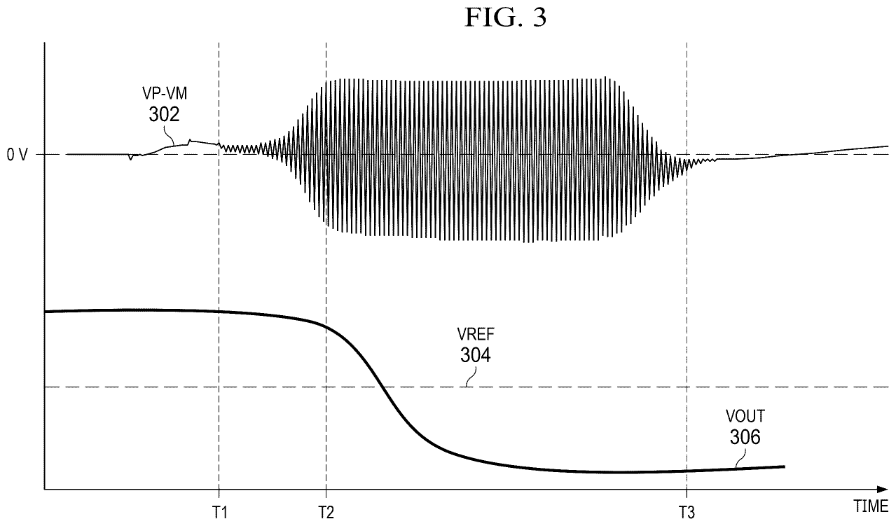

The isolation barrier circuitry 110 provides a first level of galvanic isolation within the system shown in FIG. 1. In the examples described below, the isolation barrier circuitry 110 is a transformer circuit. In other examples, the isolation barrier circuitry 110 is a different type of circuit that provides galvanic isolation and steps down the voltage of the analog differential signal. As used herein, the two portions of the differential signal output by the isolation barrier circuitry 110 are referred to as the Volts Positive (V_{P}) signal and the Volts Minus (V_{M}) signal. The V_{P} and V_{M} signals are described further in connection with FIGS. 2 and 3.

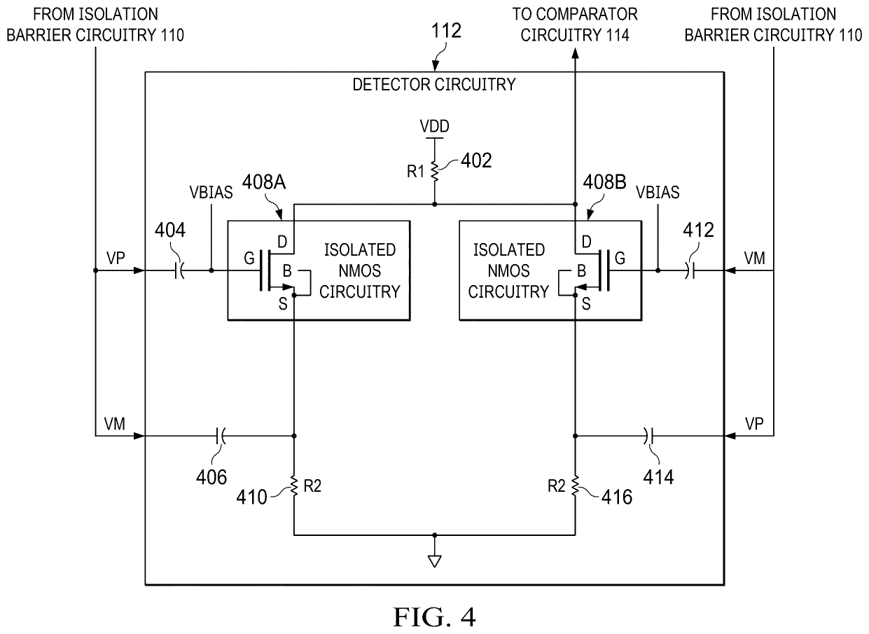

The detector circuitry 112 has input terminals that are coupled to the isolation barrier circuitry 110. The detector circuitry 112 produces an output voltage (V_{OUT}) that changes values responsive to the V_{P} and V_{M} signal. The detector circuitry 112 is implemented with isolated NMOS transistors, thereby providing a second layer of galvanic isolation to the system shown in FIG. 1. The detector circuitry 112 is described further in connection with FIGS. 4, 8, and 9.

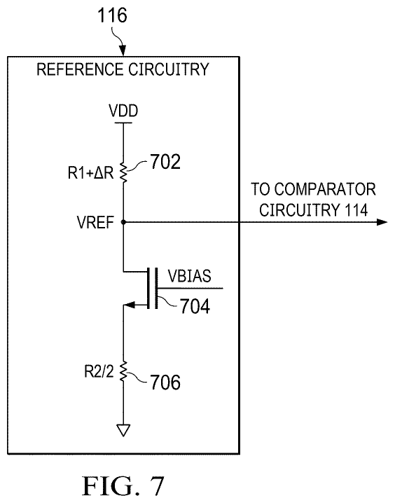

The detector circuitry 112 is coupled to comparator circuitry 114. The comparator circuitry 114 compares the V_{OUT} signal to a reference voltage (V_{REF}) produced by the reference circuitry 116. The comparator circuitry 114 then converts the analog V_{OUT} signal back to a digital value responsive to the comparison. The comparator circuitry 114 is described further in connection with FIG. 3 and the reference circuitry 116 is described further in connection with FIG. 7.

The comparator circuitry 114 stores the digital data in the output buffer 118 because, in the example of FIG. 1, the comparator circuitry 114 produces data faster than the receiver circuitry 120 reads data. The receiver circuitry 120, which is external from the isolation device 103, reads the bits from the output buffer 118 and may perform any type of operations in response to the data. In the example of FIG. 1, the receiver circuitry 120 operates at a voltage that is lower than the transmitter circuitry 102 and is safe for human interaction.

The receiver circuitry 120 expects the bits stored in the output buffer 118 to be an accurate recreation of the bits originally stored in the input buffer 104. Thus, the isolated NMOS transistors and other components within the detector circuitry 112 must operate quickly and reliably to keep pace with the high data transfer rates of the analog differential signal.

FIG. 2 is a graph illustrating an example implementation of the On-Off-Keying (OOK) format used to transmit data in FIG. 1. FIG. 2 includes example signals 202, 204, and 206 on a shared time axis.

The signal 202 represents the digital outputs produced by the transmitter circuitry 102 over time. The signal 202 shows the transmitter circuitry 102 switches from a logical 0 to a logical 1 at T1. The transmitter circuitry 102 then returns to outputting a logical 0 at T2.

The signal 204 represents the differential signal output by the multiplier circuitry 106 and formatted using OOK. Accordingly, the signal 204 represents how the value (V_{P}−V_{M}) changes over time. In response to detecting the switch to a logical 1 at T1, the multiplier circuitry 106 changes the signal 204 so that the value of (V_{P}−V_{M}) alternates at a high frequency. Later, in response to detecting the switch to a logical 0 at T2, the multiplier circuitry 106 changes the signal 204 again so that (V_{P}−V_{M}) is approximately 0 Volts.

The signal 206 represents the digital values that are output by the comparator circuitry 114. The signal 206 shows that the comparator circuitry 114 interprets the high frequency sections of the signal 204 as a logical 1 and the zero volt sections of the signal 204 as a logical 0. Accordingly, the receiver circuitry 120 obtains a copy of the digital bits sent by the transmitter circuitry 102 (that are shifted in time due to propagation delay) when the components of FIG. 1 operate properly.

FIG. 3 is a graph illustrating an example implementation of the V_{P}, V_{M}, V_{REF}, and V_{OUT} signals of FIG. 1. FIG. 3 includes example signals 302, 304, and 306 on a shared time axis. The timestamps of FIG. 3 are independent of the timestamps of FIG. 2.

Like the signal 204, the signal 302 represents the differential signal output by the multiplier circuitry 106 (e.g., the value (V_{P}−V_{M})). The signal 304 represents the V_{OUT} signal produced by the detector circuitry 112 and the signal 306 refers the V_{REF} signal produced by the reference circuitry 116. Before T1, the signal 302 is at 0 V and V_{OUT} is greater than V_{REF}.

FIG. 3 shows that the amplitude of the V_{OUT} signal begins to decrease at T1, when the signal 302 transitions from 0 V to a nonzero value. The signal 302 shows that the alternating differential signal reaches its peak swing (e.g., the difference between the local maximums and the local minimums is at its greatest value) at approximately T2. In turn, the signal 304 shows V_{OUT} decreases at a faster rate around T2, eventually becoming less than V_{REF}. The value of V_{OUT} then plateaus because the isolated NMOS circuits within the detector circuitry 112 saturate. Finally, at T3, the (V_{P}−V_{M}) returns to approximately 0 V. In response, the signal 304 shows the value of V_{OUT} begins to return to the value it was at before T1.

In examples described herein, the comparator circuitry 114 outputs a logical 0 when V_{OUT} is greater than V_{REF} and outputs a logical 1 when V_{OUT} is less than V_{REF}. In other examples, the comparator circuitry 114 outputs the opposite logical values in response to the foregoing comparison. Accordingly, the accuracy of the analog to digital conversion performed by the comparator circuitry 114 depends on how much the detector circuitry 112 can change the value of V_{OUT}. For example, consider a hypothetical where the signal 302 remains the same as shown in FIG. 3, but the gain of the detector circuitry 112 is sufficiently small that the signal 306 instead plateaus at a value greater than V_{REF}. In such a hypothetical, the comparator circuitry 114 incorrectly produces a logical 0 from T1 to T3 because the low gain of the detector circuitry 112 prevented the circuit from changing V_{OUT} enough to inform the comparator circuitry 114 that the OOK signal represented a logical 1.

FIG. 4 is a schematic diagram of the detector circuitry 112 of FIG. 1. The detector circuitry 112 includes example resistors 402, 410, and 416, example capacitors 404, 406, 412, and 414, and example isolated NMOS circuitry 408A and 408B (collectively referred to as isolated NMOS circuits 408).

The resistor 402 has a first terminal coupled to a supply voltage terminal and a second terminal. As used herein, a supply voltage terminal refers to an electrical connection that receives a Volts Drain Drain (V_{DD}) voltage when the device is powered on. The supply voltage terminal may receive V_{DD} from any system level circuit that provides supply voltages throughout a device. The resistor 402 has a first resistance value (referred to herein as R1). The voltage at the second terminal of the resistor 402 is the V_{OUT} signal provided to the comparator circuitry 114.

The capacitor 404 has a positive terminal coupled to a first input terminal of the detector circuitry 112 and a negative terminal that is coupled to bias voltage (VBIAS) terminal. Similarly, the capacitor 406 has a positive terminal coupled to the second input terminal of the detector circuitry 112 and a negative terminal. When the detector circuitry is powered on, the first input terminal receives the V_{P} signal and the second input terminal receives the V_{M} signal from the isolation barrier circuitry 110.

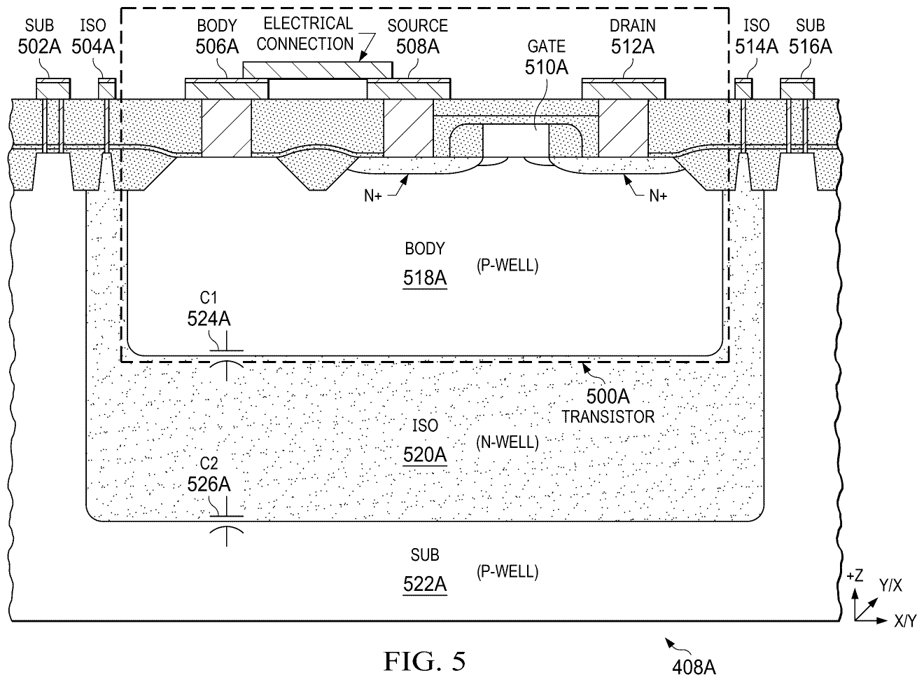

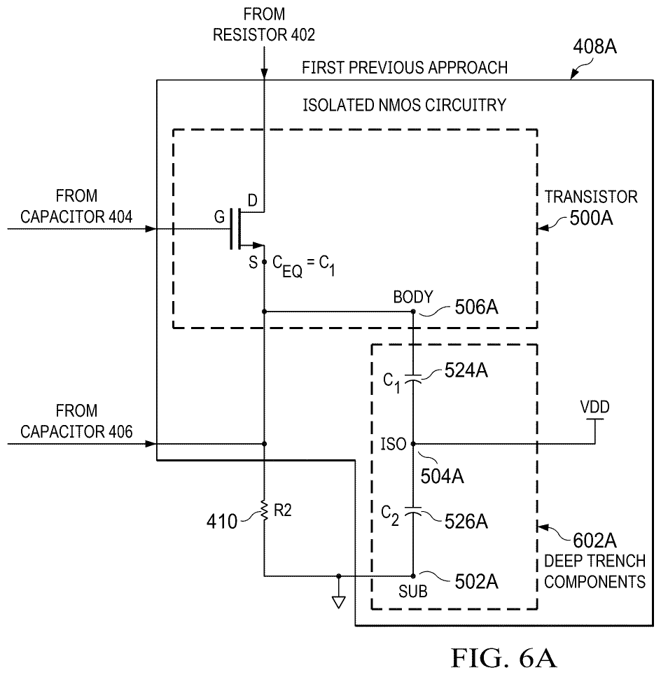

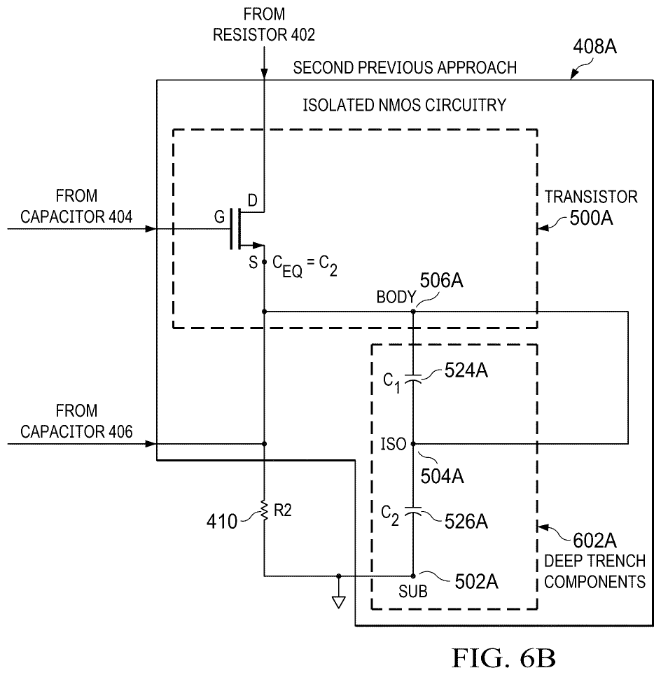

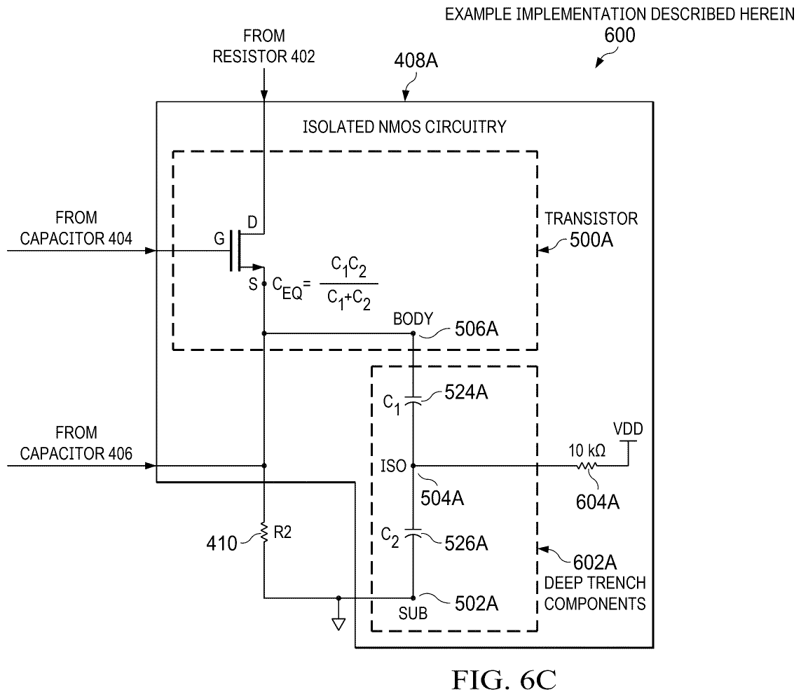

The isolated NMOS circuitry 408A includes an isolated transistor having: a drain terminal coupled to the second terminal of the resistor 402, a gate terminal coupled to the negative terminal of the capacitor 404, and a source terminal coupled to the negative terminal of the capacitor 406. The isolated transistor also has a base terminal that is coupled to its source terminal so that the transistor remains isolated from the ground plane used across the IC that implements the isolated NMOS circuitry 408A. The isolated NMOS circuitry 408A also includes parasitic capacitors that occur due to how the transistor is galvanically isolated from the rest of the IC. The parasitic capacitors are described further in connection with FIGS. 5 and 6A-6C.

The resistor 410 has a first terminal coupled to both the negative terminal of the capacitor 406 and the source terminal of the isolated NMOS circuitry 408A. The resistor 410 also has a second terminal coupled to the ground plane of the IC. The resistor 410 has a second resistance value (referred to herein as R2).

The capacitor 412 has a positive terminal coupled to a third input terminal of the detector circuitry 112 and a negative terminal that is coupled to bias voltage (VBIAS) terminal. Similarly, the capacitor 414 has a positive terminal coupled to the fourth input terminal of the detector circuitry 112 and a negative terminal. When the detector circuitry is powered on, the third input terminal receives the V_{M} signal and the fourth input terminal receives the V_{P} signal from the isolation barrier circuitry 110.

The isolated NMOS circuitry 408B includes the same components as the isolated NMOS circuitry 408A. Accordingly, the isolated NMOS circuitry 408B includes an isolated transistor having: a drain terminal coupled to the second terminal of the resistor 402, a gate terminal coupled to the negative terminal of the capacitor 412, a source terminal coupled to the negative terminal of the capacitor 414, and a base terminal coupled to its source terminal.

The resistor 416 has a first terminal coupled to both the negative terminal of the capacitor 414 and the source terminal of the isolated NMOS circuitry 408B. The resistor 416 also has a second terminal coupled to the ground plane of the IC. The resistor 416 has the same resistance value as the resistor 410 (R2).

In the example of FIG. 4, the transistors in the isolated NMOS circuits 408 are isolated n-channel metal-oxide semiconductor field-effect transistors (MOSFETs). Alternatively, the transistors in the isolated NMOS circuits 408 may be isolated n-channel field-effect transistors (FETs), isolated n-channel insulated-gate bipolar transistors (IGBTs), isolated n-channel junction field effect transistors (JFETs), isolated NPN bipolar junction transistors (BJTs) or, with slight modifications, isolated p-type equivalent devices. Furthermore, the transistors in the isolated NMOS circuits 408 may be implemented in/over a silicon substrate (Si), a silicon carbide substrate (SiC), a gallium nitride substrate (GaN) or a gallium arsenide substrate (GaAs).

The capacitors 404, 406, the isolated NMOS circuitry 408A, and the resistor 410 collectively form a first half of the circuit that operates when V_{P} increases and V_{M} decreases during a high frequency portion of the analog differential signal (e.g., when (V_{P}−V_{M}) is >0 V). During such an example, the difference between the voltage at the gate terminal and source terminal (V_{GS}) of the isolated NMOS circuitry 408A is a positive voltage that exceeds a threshold, so the isolated transistor turns on and current flows from drain to source in the isolated NMOS circuitry 408A. The current then flows through the resistor 410 and to the ground plane, lowering the value of V_{OUT} in the process. Notably, current does not flow through isolated NMOS circuitry 408B when (V_{P}−V_{M}) is >0 V because Vos of the isolated transistor is a negative voltage.

The capacitors 412, 414, the isolated NMOS circuitry 408B, and the resistor 416 collectively form a second half of the circuit that operates when V_{M} increases and V_{P} decreases during a high frequency portion of the analog differential signal (e.g., when (V_{P}−V_{M}) is <0 V). During such an example, the difference between the voltage at the gate terminal and source terminal (V_{GS}) of the isolated NMOS circuitry 408B is a positive voltage that exceeds a threshold, so the isolated transistor turns on and current flows from drain to source in the isolated NMOS circuitry 408B. The current then flows through the resistor 416 and to the ground plane, lowering the value of V_{OUT} in the process. Notably, current does not flow through isolated NMOS circuitry 408A when (V_{P}−V_{M}) is <0 V because Vas of the isolated transistor is a negative voltage.

During high frequency portions of the (V_{P}−V_{M}) signal, the first half and second half of the detector circuitry 112 alternate to decrease the value of V_{OUT}. When (V_{P}−V_{M}) is approximately 0 V, however, the Vas is not large enough to activate either transistor in the isolated NMOS circuits 408. Accordingly, the resistor 402 and V_{DD} pull the value of V_{OUT} up to its previous value.

FIG. 4 shows that the rate at which V_{OUT} changes is responsive to the amount of current that flows through the isolated NMOS circuits 408. Previous approaches of implementing the detector circuitry 112 implement the isolated NMOS circuits 408 in a manner that supports a comparatively small amount of current flow, thereby leading to a small gain of the detector circuitry 112 and poor SnR. In contrast, examples described herein implement the isolated NMOS circuits 408 that support a comparatively large amount of current flow, thereby increasing the gain of the detector circuitry 112 and improving SnR.

FIG. 5 is a profile view of an example implementation of the isolated NMOS circuitry 408A of FIG. 4. FIG. 5 includes an example transistor 500A, the capacitors 524A and 526A, as well as example substrate (SUB) terminals 502A and 516A, an example isolation (ISO) region 520A, an example SUB region 522A, and example ISO terminals 504A and 514A. The transistor 500A includes an example body terminal 506A, an example source terminal 508A, an example gate terminal 510A, an example drain terminal 512A, and an example body region 518A.

FIG. 5 is a cross section of an IC that implements the isolated NMOS circuitry 408A. Accordingly, the body terminal 506A, the source terminal 508A, the gate terminal 510A, and the drain terminal 512A are implemented at the top of the IC so the transistor 500A can be electrically coupled to other components (using, e.g., Surface-mount technology (SMT)). For example, a wire, interconnect, or other conductive material forms an electrical connection between the body terminal 506A and the source terminal 508A at the surface of the IC. In contrast, the horizontal portions of the ISO region 520A and SUB region 522A are physically implemented below the body region 518A and the terminals of the transistor 500A. Therefore, the horizontal portions of the ISO region 520A and SUB region 522A are not directly accessible. Rather, the SUB terminals 502A and 516A allow other components to connect to the horizontal portion of the SUB region 522A at the surface of the IC. Similarly, the ISO terminals 504A and 514A enable other components to connect to the horizontal portion of the ISO region 520A at the surface of the IC. In some examples, the horizontal portions of the ISO region 520A and SUB region 522A are referred to as layers.

The transistor 500A implements an NMOS because the source terminal 508A and drain terminal 512A both connect to n-doped regions, while the body terminal 506A connects to a p-doped well (e.g., the body region 518A). Thus, when the Vas exceeds a threshold voltage, the portion of the body region 518A beneath the gate terminal 510A supports the exchange of electrons between the two n-doped regions, and current flows from the drain terminal 512A to the source terminal 508A.

The SUB region 522A represents a substrate material that may be implemented throughout the bottom of the IC. Accordingly, in examples described herein, the substrate region 522A is used as a ground plane by multiple components on the IC. To maintain galvanic isolation from these other components, the transistor 500A cannot be electrically coupled to the SUB region 522A. However, both the SUB region 522A and the body region 518A at the bottom of the transistor 500A are p-doped. Thus, implementing the two regions directly on top of one another would form an inadvertent electrical connection that couples the body of the transistor 500A to the ground plane.

The isolated NMOS circuitry 408A includes the ISO region 520A to prevent the transistor 500A from coupling to the ground plane. The ISO region 520A includes an n-doped well that both physically and electrically separates the body region 518A from the SUB region 522A, thereby isolating the transistor 500A from ground. Furthermore, the vertical portions of the ISO region 520A and SUB region 522A physically and electrically isolate the transistor 500A from adjacent components that may exist nearby in the x or y dimensions of the IC. In some examples, ISO region 520A and SUB region 522A are referred to as Deep Trench components because: a) the vertical portions of the region provide galvanic isolation as described above, and b) the vertical portions are implemented across a significant distance in the z dimension when compared to the depth of the horizontal layers.

While the ISO region 520A is needed to galvanically isolate the transistor 500A, its implementation also introduces parasitic capacitance between adjacent layers in the z dimension. For example, the parasitic capacitance between the body region 518A and the ISO region 520A is labelled herein as capacitor 524A with a capacitance value of C1. Similarly, the parasitic capacitance between the ISO region 520A and the SUB region 522A is labelled herein as capacitor 526A with a capacitance value of C2. In examples described herein, the capacitors 524 and 526 within isolated NMOs circuits 408 may also be referred to as part Deep Trench Components because they would not exist without the ISO region 520A.

While FIG. 5 shows the isolated NMOS circuitry 408A as an example, the description of FIG. 5 applies equally to the isolated NMOS circuitry 408B because both isolated NMOS circuits 408 include the same components and operate in the same manner described above. Furthermore, while examples described in FIGS. 4-9 refer to isolated NMOS circuitry, other detector circuits implemented according to the examples described herein may use isolated PMOS circuits. In such examples, the body region 518A is an n-doped well, the ISO region 520A is a p-doped well, and the SUB region 522A is an n-doped well.

Each of FIGS. 6A, 6B, and 6C includes a schematic representation of the isolated NMOS circuitry 408A and the resistor 410. The schematic representation of the isolated NMOS circuitry 408A shows the body terminal 506A, isolation terminal 504A, and substrate terminal 502A as electrical nodes. In each of FIGS. 6A, 6B, and 6C, the body terminal 506A and source terminal 508A of the transistor 500A are shown as the same electrical node because the two components are electrically connected as shown in FIGS. 4 and 5. Furthermore, within the Deep Trench components 602A, the capacitor 524A separates the body node from the ISO terminal 504A, the capacitor 526A separates the ISO terminal 504A from the SUB terminal 502A, and the SUB terminal 502A is connected to the system-level ground plane in each of FIGS. 6A, 6B, and 6C.

FIG. 6A is a schematic diagram of a first previous approach to implement the isolated NMOS circuitry 408A of FIG. 4. In FIG. 6A, the ISO terminal 504A is coupled directly to the supply voltage terminal (e.g., is configured to receive V_{DD}). Accordingly, the charge of the capacitor 526A is not responsive to changes in the AC signal (V_{P}−V_{M}) in FIG. 6A because DC voltages (e.g., V_{DD} and ground) are applied at the positive and negative terminals. Rather, when V_{M} is a nonzero value during high frequency portions of the differential signal, current flowing from the negative terminal of the capacitor 404 charges the capacitor 524A but not the capacitor 526A. Thus, the equivalent capacitance (C_{EQ}) at the source terminal in FIG. 6A is C1. Notably, C1 is a comparatively large value for C_{EQ}. Accordingly, previous approaches to implement the isolated NMOS circuitry 408A as shown in FIG. 6A suffer from a comparatively small amount of current flow because C_{EQ}=C1 must be charged before all current from the drain terminal flows to the resistor 410.

FIG. 6B is a schematic diagram of a second previous approach to implement the isolated NMOS circuitry 408A of FIG. 4. In FIG. 6B, the ISO terminal 504A is coupled directly to the source terminal 508A and the body terminal 506A. When V_{M} is a nonzero value during high frequency portions of the differential signal, the connection of the ISO terminal 504A in FIG. 6B acts as an alternate path that current takes to ignore the capacitor 524A. Accordingly, in such situations, the current flowing from the negative terminal of the capacitor 404 charges the capacitor 526A but not the capacitor 524A. Thus, the equivalent capacitance (C_{EQ}) at the source terminal in FIG. 6B is C2. Notably, C2 is a comparatively large value for C_{EQ}. Accordingly, previous approaches to implement the isolated NMOS circuitry 408A as shown in FIG. 6B suffer from a comparatively small amount of current flow because C_{EQ}=C2 must be charged before all current from the drain terminal flows to the resistor 410.

FIG. 6C is a schematic diagram of the isolated NMOS circuitry 408A of FIG. 4 that shows a first implementation 600 described in the examples herein. FIG. 6C includes an example resistor 604A having a first terminal coupled to the ISO terminal 504A and a second terminal coupled to the supply voltage terminal. The resistor 604A has a sufficiently high resistance value (e.g., 10 kiloohms in the example of FIG. 6C) so that any flow of current from V_{DD} to the capacitor 526A is negligible. As a result, when V_{M} is a nonzero value during high frequency portions of the differential signal, current flowing from the negative terminal of the capacitor 404 charges both the capacitor 524A and the capacitor 526A in series. The equivalent capacitance at the source terminal in the example of FIG. 6C is therefore given by equation (1):

$${C}_{EQ} = \frac{{C}_{1} {C}_{2}}{( {C}_{1} + {C}_{2} )} \qquad ( 1 )$$

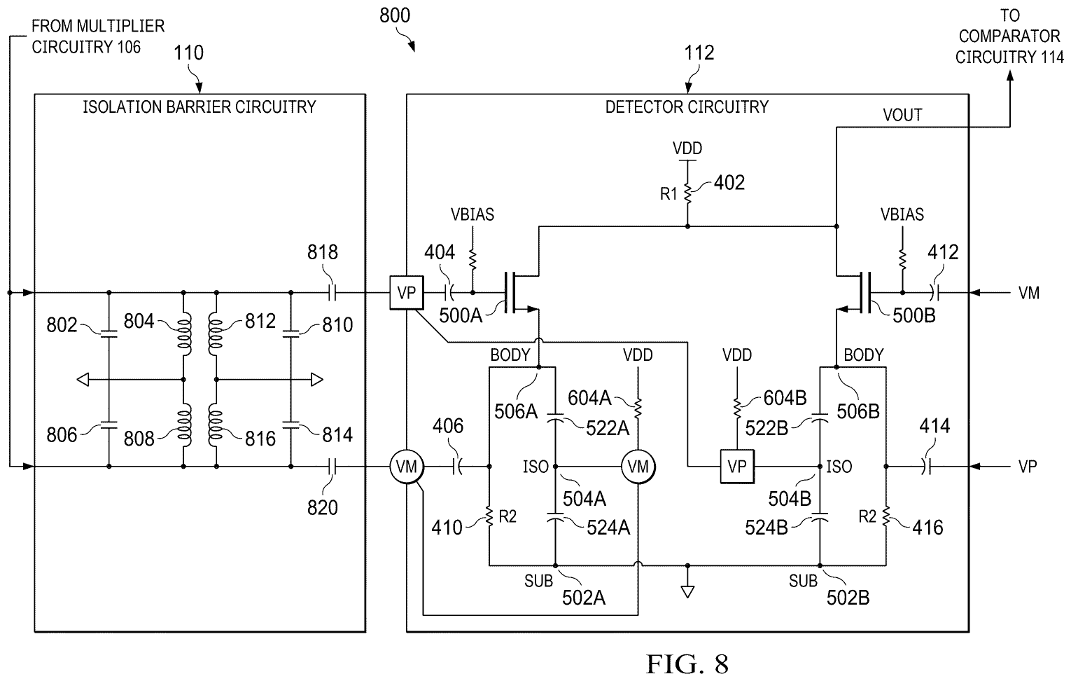

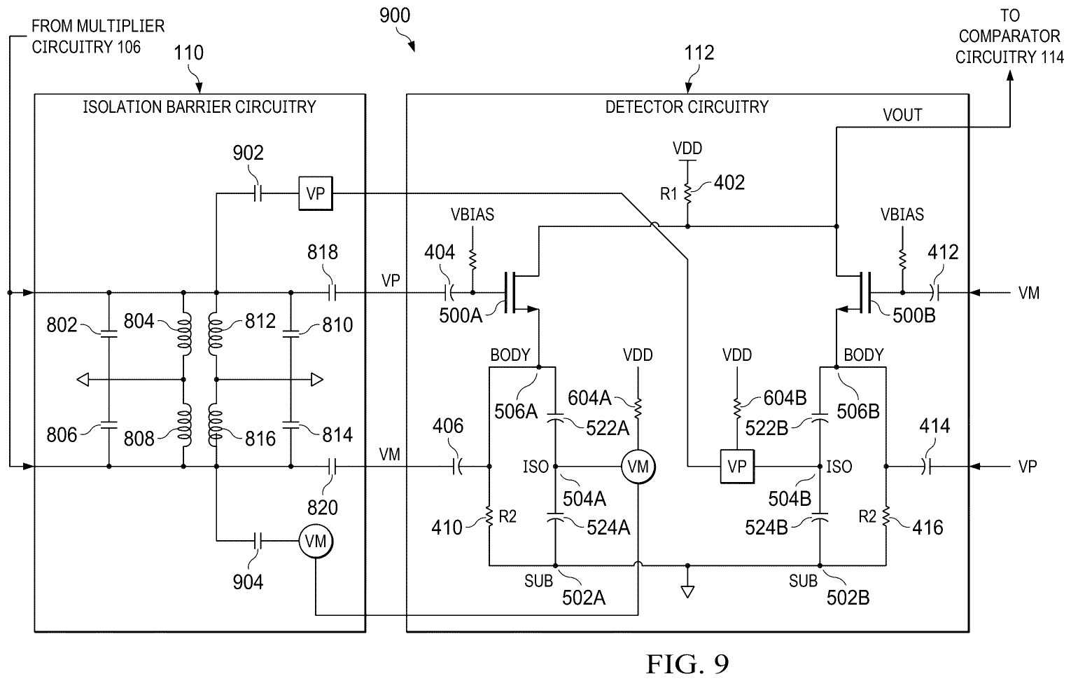

The value of C_{EQ} expressed in equation (1) is less than both C1 and C2. This is because adding capacitors in series has the equivalent effect of a single capacitor having the sum total of the plate spacing of the individual capacitors, thereby decreasing the equivalent capacitance. Thus, the resistor 604A sets the effective capacitance at the source terminal as less than both the capacitor 524A and the capacitor 526A. In turn, the first implementation 600 supports more current flow from the drain terminal to the resistor 410 the than either of the previous approaches described in FIGS. 6A and 6B. In turn, detector circuitry 112 that is implemented with the example of FIG. 6C has a higher gain, and therefore a better SnR, than previous approaches. As described in connection with FIGS. 8 and 9, the SnR of the detector circuitry 112 may be further improved by providing the V_{M} signal at the electrical node between the resistor 604A and the isolation terminal 504A.

FIG. 7 is an example schematic diagram of the reference circuitry 116 of FIG. 1. FIG. 7 includes example resistors 702 and 706, and an example transistor 704.

The resistor 702 includes a first terminal coupled to the supply voltage terminal and a second terminal coupled to the transistor 704. The voltage at the second terminal is the V_{REF} signal provided to the comparator circuitry 114. The supply voltage terminal in FIG. 7 is configured to receive the same V_{DD} signal as the supply voltage terminal shown in FIG. 4. The resistor 702 has a resistance value that is larger than the resistance value of the resistor 402 of FIG. 4. The difference between the two resistances is shown on FIG. 7 as AR.

The transistor 704 has a drain terminal coupled to the second terminal of the resistor 702, a gate terminal coupled to the bias voltage terminal, and a source terminal. The value of VBIAS in FIG. 7 is the same value of VBIAS as shown in FIG. 4.

In the example of FIG. 7, the transistor 704 are n-channel metal-oxide semiconductor field-effect transistors (MOSFETs). Alternatively, the transistor 704 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. Furthermore, the transistor 704 may be implemented in/over a silicon substrate (Si), a silicon carbide substrate (SiC), a gallium nitride substrate (GaN) or a gallium arsenide substrate (GaAs).

The resistor 706 includes a first terminal coupled to the source terminal of the transistor 704 and a second terminal coupled to ground. The resistance value of the resistor 706 is half of the resistance value of the resistors 410 and 416 (annotated in FIG. 7 as R2/2).

When powered ON, the transistor 704 acts as a current source that produces a fixed bias current I. Using this current, the reference circuitry 116 generates the value of V_{REF} shown in equation 2:

$${V}_{REF} = I ( {R}_{702} ) = I ( {R}_{1} + Δ R ) \qquad ( 2 )$$

In examples described herein, VBIAS is provided to the reference circuitry 116 by system level circuitry and the transistor 704 is ON whenever the isolation device 103 is powered ON. Thus, in examples where the isolation device 103 is powered ON, the transistor 704 continuously acts as a current source and the V_{REF} value of equation (2) is continuously provided to the comparator circuitry 114.

FIG. 8 shows a second implementation 800 of the isolated NMOS circuitry of FIG. 4 using the examples described herein. FIG. 8 is an example schematic diagram that includes the isolation barrier circuitry 110 and the detector circuitry 112 of FIG. 1. The isolation barrier circuitry 110 implements a transformer with example capacitors 802, 806, 810, 814, 818, and 820, and example inductors 804, 808, 812, and 816. The transformer enables energy to transfer from the multiplier circuitry 106 to the detector circuitry 112 wirelessly, thereby providing a layer of galvanic isolation to the system of FIG. 1. In the example of FIG. 8, the negative terminal of the capacitor 818 produces the V_{P} signal and the negative terminal of the capacitor 820 produces the V_{M} signal.

The detector circuitry 112 includes the same components described in FIG. 4, with both isolated NMOS circuits 408A and 408B implemented according to the examples described herein (e.g., with a resistor 604 between the ISO region and V_{DD}). Also, the isolated NMOS circuitry 408A in the example implementation 800 includes an electrical connection between the ISO terminal 504A, the resistor 604A, and the input terminal of the detector circuitry 112 that receives the V_{M} signal. This additional electrical connection provides two distinct nodes (source and ISO) from which the V_{M} signal charges the capacitors 524A and 526A in series, thereby supporting additional current flow from the drain terminal to the resistor 410 and further increasing the gain of the isolated NMOS circuitry 408A relative to the implementation 600. Similarly, the implementation 800 includes an electrical connection between the ISO terminal 504B, the resistor 604B, and the input terminal of the detector circuitry 112 that receives the V_{P} signal. The foregoing electrical connection further increases the gain of the isolated NMOS circuitry 408B relative to the implementation 600, further improving SnR. In some examples, the foregoing electrical connections are referred to as a short circuit between the inputs of the detector circuitry 112 and the ISO regions 522.

FIG. 9 shows a third implementation 900 of the isolated NMOS circuitry of FIG. 4 when implemented using the examples described herein. FIG. 9 is an example schematic diagram that includes the same components described above in FIG. 8. Also, the isolation barrier circuitry 110 also includes the capacitors 902 and 904 in FIG. 9. The capacitors 902 and 904 are AC coupling capacitors that are used to transmit the AC differential signal from one node to another. Thus, while the capacitor 404 still receives the V_{P} signal from the capacitor 818 via an input terminal of the detector circuitry 112, the resistor 604B and the ISO terminal 504B in the example implementation 900 receive the V_{P} signal from the capacitor 902. Similarly, the resistor 604A and the ISO terminal 504A in the example implementation 900 receive the V_{M} signal from the capacitor 904.

Like the implementation 800 shown in FIG. 8, the electrical connections in the implementation 900 that provide portions of the differential signal directly to the ISO regions 522 of the isolated NMOS circuits 408 improve the gain of the detector circuitry 112. A designer or manufacturer of the system of FIG. 1 may utilize one of the implementations 800 or 900 instead of the other for any reason, including whether isolation barrier circuitry 110 includes an AC coupling capacitor.

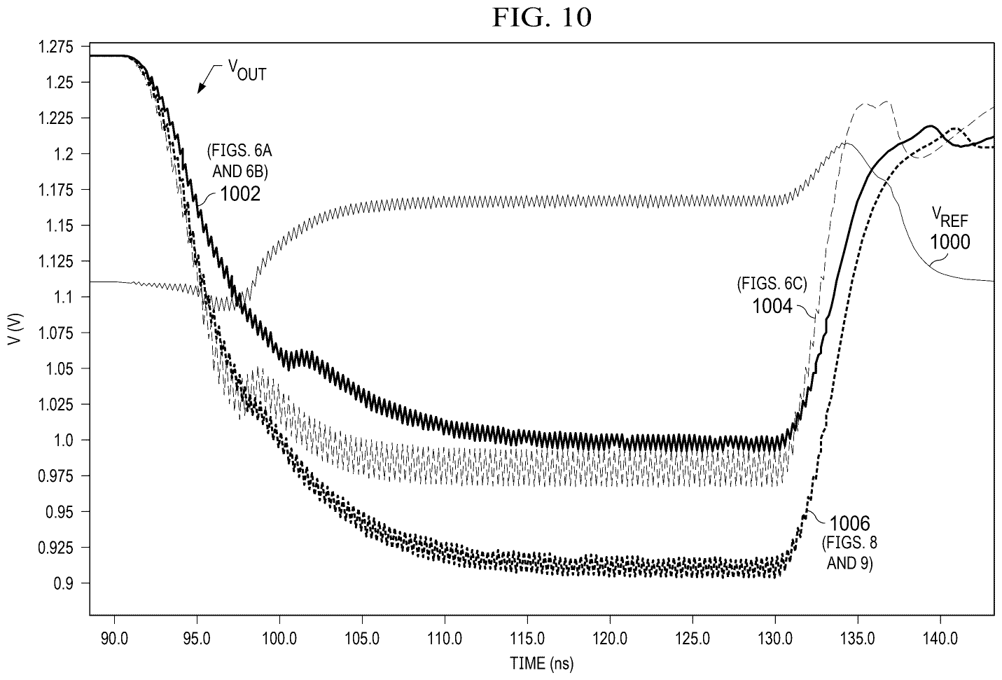

FIG. 10 is a graph illustrating the performance of the isolated NMOS circuits of FIG. 4. FIG. 10 includes an example V_{REF} signal 1000 and example V_{OUT} signals 1002, 1004, 1006. The V_{OUT} signals represent how different versions of the detector circuitry 112 change the value of V_{OUT} responsive to receiving a high frequency portion of the OOK signal from the isolation barrier circuitry 110.

The signal 1002 represents a version of the detector circuitry 112 in which the isolated NMOS circuits 408 were implemented using a previous approach from either of FIG. 6A or FIG. 6B. The signal 1002 shows that the lowest value V_{OUT} reaches is approximately 1.0 V, a comparatively high value. Furthermore, the signal 1002 does not reach 1.0 V until approximately 110 nanoseconds, a comparatively long amount of time. Thus, if the amplitude of (V_{P}−V_{M}) is less than an expected value during the high frequency portion of the signal, or if the OOK signal only alternates at a high frequency portion for a relatively short period, the previous approaches may signal degradation issues due to an inability to bring the V_{OUT} signal 1002 under the V_{REF} signal 1000.

The signal 1004 represents a version of the detector circuitry 112 in which the isolated NMOS circuits 408 were implemented using the example implementation 600 shown in FIG. 6. The signal 1004 shows that the addition of the resistor 604, by itself, improves the performance of the detector circuitry 112 by lowering V_{OUT} down to approximately 0.97 V. Furthermore, the signal 1004 crosses 1.0 V at approximately 100 ns, which is quicker than the signal 1002. Thus, the implementation 600 described herein has a higher margin for error and better SnR than previous approaches.

The signal 1006 represents a version of the detector circuitry 112 in which the isolated NMOS circuits 408 were implemented using either of the implementations 800 or 900. The signal 1006 shows that adding a short circuit between the V_{M} signal, the resistor 604A, and the isolation region 520A, (and making the same short with the V_{P} signal to the isolated NMOS circuitry 408B) further improves the performance of the detector circuitry 112 by lowering V_{OUT} down to approximately 0.91 V. Thus, the implementations 800 and 900 described herein have a higher margin for error and better SnR than both the implementation 600 and previous approaches.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern responsive to the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” “fourth”, “fifth”, etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that use isolated NMOS transistors to increase the gain of detector circuitry. Described systems, apparatus, articles of manufacture, and methods improve the efficiency of the detector circuitry using a resistor that connects an isolated region within the Deep Trench components to a supply voltage, thereby reducing the effective capacitance at the source terminal and increasing the amount of current that flows through the transistor. In some examples, the detector circuitry 112 also includes an electrical connection that provides part of the differential input signal directly to the isolated region, thereby charging the parasitic capacitors from two nodes and improving the gain further. Described systems, apparatus, articles of manufacture, and methods are also directed to one or more improvement(s) in the operation of a machine such as a computer or other electronic, electromechanical, or mechanical device.

What is claimed is:

1. An apparatus comprising:
a first resistor having a first terminal and a second terminal;
a transistor having a gate terminal coupled to a first input terminal, a source terminal coupled to a second input terminal, a body terminal coupled to the source terminal, and a drain terminal coupled to the second terminal of the first resistor;
a substrate terminal coupled to ground;
an isolation terminal that physically and electrically separates the transistor from the substrate terminal;
a second resistor having a first terminal coupled to the isolation terminal and a second terminal; and
a third resistor having a first terminal coupled to the source terminal of the transistor and a second terminal coupled to ground.

2. The apparatus of claim 1, further including a capacitor having a first terminal coupled to the first input terminal and a second terminal coupled to the gate terminal of the transistor.

3. The apparatus of claim 1, wherein:
the isolation terminal is coupled to an isolation region;
the substrate terminal is coupled to a substrate region; and
the transistor, the substrate region, and the isolation region are implemented on the same integrated circuit (IC).

4. The apparatus of claim 3, wherein the isolation region and the substrate region galvanically isolate the transistor from adjacent components on the IC.

5. The apparatus of claim 3, wherein:
the substrate region is a ground plane shared by other components of the IC; and
the isolation region galvanically isolates the transistor from the substrate region.

6. The apparatus of claim 1, further including:
a second transistor having a gate terminal coupled to a third input terminal, a source terminal coupled to a fourth input terminal, a body terminal coupled to the source terminal, and a drain terminal coupled to the second terminal of the first resistor;
a second substrate terminal coupled to ground;
a second isolation terminal that separates the second transistor from the second substrate terminal;
a fourth resistor having a first terminal coupled to the second isolation terminal and a second terminal; and
a fifth resistor having a first terminal coupled to the source terminal of the second transistor and a second terminal coupled to ground.

7. The apparatus of claim 1, further including reference circuitry configured to generate a reference voltage.

8. The apparatus of claim 7, wherein the reference circuitry includes:
a fourth resistor having a first terminal and a second terminal;
a second transistor having a drain coupled to the second terminal of the fourth resistor, a gate terminal configured to receive a bias voltage; and a source terminal coupled to a fifth resistor, wherein a voltage at the gate terminal is the reference voltage.

9. The apparatus of claim 7, wherein:
a voltage at the second terminal of the first resistor is an output voltage; and
the apparatus is coupled to comparator circuitry that is configured to generate a digital value responsive to a comparison of the output voltage and the reference voltage.

10. The apparatus of claim 1, wherein:
the apparatus is rated to operate at a first voltage;
the first input terminal and the second input terminal are coupled to isolation barrier circuitry;
the isolation barrier circuitry is configured to receive a second voltage that is larger than the first voltage; and
the isolation barrier circuitry is configured to provide, using the first input terminal and the second input terminal, a differential signal.

11. An apparatus comprising:
a first resistor having a first terminal and a second terminal;
a transistor having a gate terminal coupled to a first input terminal, a source terminal configured to a second input terminal, a body terminal coupled to the source terminal, and a drain terminal coupled to the second terminal of the first resistor;
a substrate terminal coupled to ground;
an isolation terminal coupled to the second input terminal, wherein the isolation terminal physically and electrically separates the transistor from the substrate terminal;
a second resistor having a first terminal coupled to the isolation terminal and a second terminal; and
a third resistor having a first terminal coupled to the source terminal of the transistor and a second terminal coupled to ground.

12. The apparatus of claim 11, wherein:
the isolation terminal is coupled to an isolation region;
the substrate terminal is coupled to a substrate region; and
the first resistor, the transistor, the substrate region, the isolation region, the second resistor, and the third resistor are implemented on a same integrated circuit (IC); and
the IC includes a first input terminal coupled to an isolation barrier and a second input terminal coupled to the isolation barrier.

13. The apparatus of claim 12, wherein:
the apparatus includes a short circuit from the first input terminal of the IC to the isolation terminal; and
the short circuit provides a first input signal to the isolation region.

14. The apparatus of claim 12, wherein:
the apparatus includes a short circuit from the first input terminal of the IC to the isolation region; and
the short circuit provides a first input signal to the isolation terminal.

15. An integrated circuit (IC) comprising:
a transistor having a gate terminal, a drain terminal, a source terminal, and a body region coupled to the source terminal;
a substrate region coupled to ground;
an isolation region that physically and electrically separates the transistor from the substrate region; and
a resistor having a first terminal coupled to the isolation region and a second terminal coupled to a supply voltage terminal.

16. The IC of claim 15, wherein:
the isolation region introduces a first parasitic capacitance between the body region and the isolation region;
the isolation region introduces a second parasitic capacitance between the isolation region and the substrate region; and
the effective capacitance at the source terminal as less than both the first parasitic capacitance and the second parasitic capacitance due to the resistor.

17. The IC of claim 15, wherein:
the body region is p-doped;
the isolation region is n-doped; and
the substrate region is p-doped.

18. The IC of claim 15, wherein:
the body region is n-doped;
the isolation region is p-doped; and
the substrate region is n-doped.

19. The IC of claim 15, further including a short circuit between the first terminal of the resistor and an input terminal of the IC.

20. The IC of claim 15, further including a short circuit between the first terminal of the resistor and an alternating current (AC) coupling capacitor in isolation barrier circuitry.
